(19) United States
(12) Patent Application Publication
(10) Pub. No.: US 2008/0017880 A1
(43) Pub. Date: Jan. 24, 2008

(54) SI-SUBSTRATE AND STRUCTURE OF OPTO-ELECTRONIC PACKAGE HAVING THE SAME

(76) Inventor: Hung-Yi Lin, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/612,490

(22) Filed: Dec. 19, 2006

(30) Foreign Application Priority Data
Jul. 24, 2006 (TW) 095126950

(51) Int. Cl. H01L 33/00

(52) U.S. Cl. 257/103

(57) ABSTRACT

Disclosed herein is a structure of an opto-electronic package having a Si-substrate. Si-substrates are manufactured in batch utilizing micro-electromechanical processes or semiconductor processes, so that these Si-substrates are made with great precision and full of varieties. Based on the material characteristics of the Si-substrate, and the configuration of the components, such as the connecters, opto-electronic devices, depressions, solder bumps, etc., the present invention can improve the optical effect, the heat dissipating effect, and the reliability of the structure of opto-electronic package, and simplifies the complexity of the structure of opto-electronic package.

### BACKGROUND OF THE INVENTION

1. Field of the Invention

The present invention generally relates to the field of opto-electronic package structures, and more particularly, to an opto-electronic package structure formed by the micro-electromechanical processes or the semiconductor processes.

2. Description of the Prior Art

In recent years, a new application field of high illumination light emitting diodes (LEDs) has been developed. Different from a common incandescent light, a cold illumination LED has the advantages of low power consumption, long device lifetime, no idling time, and quick response speed. In addition, since the LED also has the advantages of small size, vibration resistance, suitability for mass production, and ease of fabrication as a tiny device or an array device, it has been widely applied in display apparatuses and indicating lamps used in information, communication, and consumer electronic products. The LEDs are not only utilized in outdoor traffic signal lamps or various outdoor displays, but are also very important components in the automotive industry. Furthermore, the LEDs work well in portable products, such as cellular phones and as backlights of personal data assistants. These LEDs have become necessary key components in the highly popular liquid crystal displays because they are the best choice when selecting the light source of the backlight module.

Please refer to FIG. 1 and FIG. 2. FIG. 1 is a schematic top view diagram showing a prior art surface mount device (SMD) LED package structure 10, and FIG. 2 is a cross section diagram illustrating the prior art SMD LED package structure 10 along 1-1′ line shown in FIG. 1. As shown in FIG. 1 and FIG. 2, an SMD LED package structure 10 comprises a cup-structure substrate 12, a lead frame 14, an opto-electronic device 16, conducting wires 18 and 20, and a sealant 22. As a semiconductor device comprising a positive electrode and a negative electrode (not shown), the opto-electronic device 16 is illuminated by receiving power from an external voltage source and connected to the lead frame 14 by the conducting wires 18 and 20. Situated in the cup-structure substrate 12, the lead frame 14 is extended to the outer surface of the cup-structure substrate 12, which will be electrically connected to a printed circuit board (PCB) 24.

In order to construct the prior art LED package 10, the cup-structure substrate 12 should be completed first, and then the sealant 22 covers the opto-electronic device 16 by means of molding or sealant injection. After the construction of the prior art LED package 10 is completed, at least a surface mounting process is performed to mount the LED packages 10 on the PCB 24 individually. As a result, it is almost impossible to produce the LED packages 10 in batch, and the manufacturing process of the electronic products is too complicated and tedious. As applied in a LED package 10 with high power, the cup-structure substrate 12 of the opto-electronic device 16 is unavoidably overheated, which may eventually result in a reduction of light intensity or failure of the entire device. Due to the significantly large volume of the single LED package 10 and the heat radiating demand required by a LED package 10 with high power, the designed size and the heat dissipating efficiency of the whole LED package 10 are greatly limited.

### SUMMARY OF THE INVENTION

It is the primary object of the present invention to provide an opto-electronic package structure having a Si-substrate. Accordingly, the present invention can improve the optical effect, the heat dissipating effect, and the reliability of the opto-electronic package structure, the opto-electronic package structure can be manufactured in batch, and the complexity of the opto-electronic package structure can be simplified.

According to the claimed invention, an opto-electronic package structure having Si-substrates is disclosed. The opto-electronic package structure includes a silicon wafer. The silicon wafer defines a plurality of Si-substrates therein. Each of the Si-substrates includes a plurality of connecters and at least an opto-electronic device electrically connected to the connecters. The Si-substrates include at least two different outline shapes.

Since the Si-substrates can be produced in a batch system utilizing micro-electromechanical processes or semiconductor processes, these Si-substrates are made with great precision and full of varieties. According to the characteristics of Si-substrate and the arrangement of the components, such as the connecters, the opto-electronic device, the cup-structure and the flip-chip bump on Si-substrate, the present invention can simplify the complexity of the components in the opto-electronic package structure, and increase the optical effect, the heat-dissipating effect and the packaging reliability of the opto-electronic package structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view diagram showing a prior art surface mount device (SMD) LED package structure.

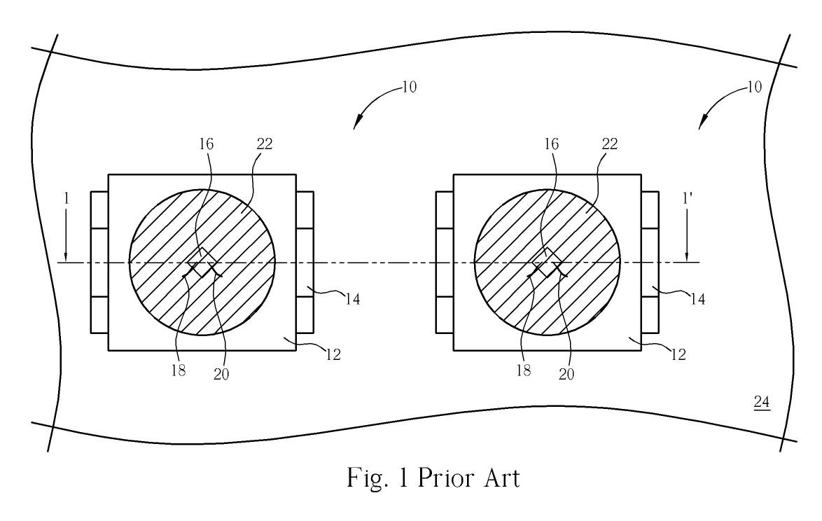

FIG. 2 is a cross section diagram illustrating the prior art SMD LED package structure along 1-1′ line shown in FIG. 1.

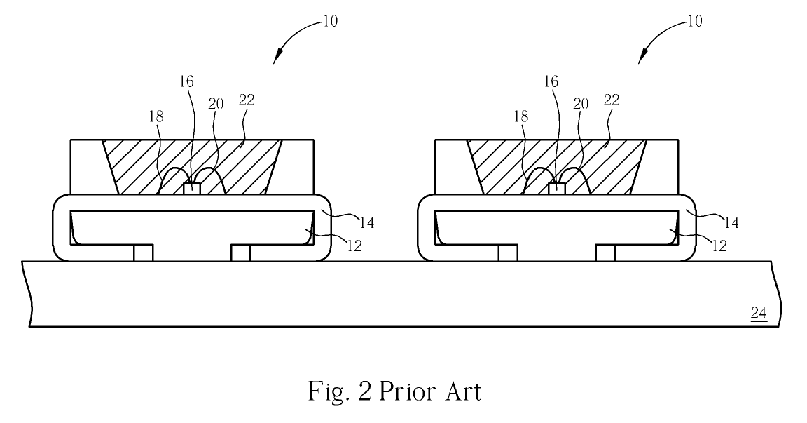

FIG. 3 is a cross-sectional schematic diagram illustrating an opto-electronic package structure having Si-substrates according to a first preferred embodiment of the present invention.

FIG. 4 is a cross-sectional schematic diagram illustrating an opto-electronic package structure having Si-substrates according to a second preferred embodiment of the present invention.

FIG. 5 is a cross-sectional schematic diagram illustrating an opto-electronic package structure having Si-substrates according to a third preferred embodiment of the present invention.

FIG. 6 is a cross-sectional schematic diagram illustrating an opto-electronic package structure having Si-substrates according to a fourth preferred embodiment of the present invention.

FIG. 7 is a cross-sectional schematic diagram illustrating an opto-electronic package structure having Si-substrates according to a fifth preferred embodiment of the present invention.

FIG. 8 is a cross-sectional schematic diagram illustrating an opto-electronic package structure having Si-substrates according to a sixth preferred embodiment of the present invention.

### DETAILED DESCRIPTION

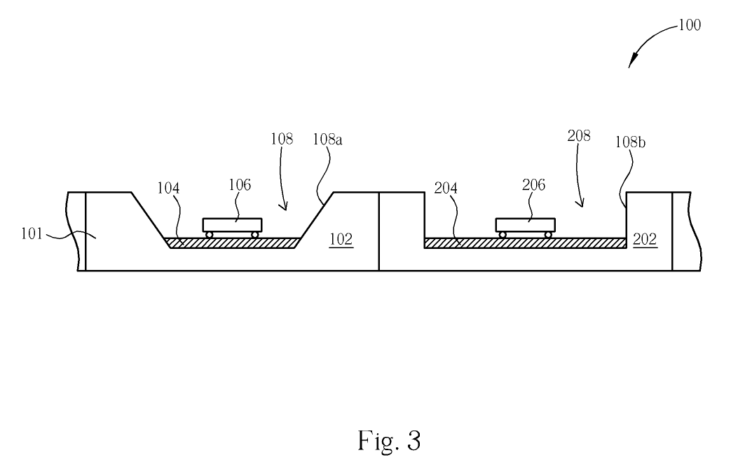

Please refer to FIG. 3. FIG. 3 is a cross-sectional schematic diagram illustrating an opto-electronic package structure having Si-substrates according to a first preferred embodiment of the present invention. As shown in FIG. 3, an opto-electronic package structure 100 includes a silicon wafer 101, and at least two Si-substrates 102, 202 are defined in the silicon wafer 101 according to the product design. The Si-substrate 102 includes a plurality of connecters 104 and at least an opto-electronic device 106 electrically connected to the connecters 104 through bumps. The Si-substrate 202 includes a plurality of connecters 204 and at least an opto-electronic device 206 electrically connected to the connecters 204 through bumps. Each of the connecters 104, 204 can be a flat metal layer having large area or a metal circuit layer having circuits therein, and the positive electrode of each opto-electronic device 206 will not short with the negative electrode through the connecters 104, 204. As shown in the figure, the Si-substrate 102 includes a cup-structure 108, and the Si-substrate 202 includes a cup-structure 208. Because the Si-substrates 102, 202 can be manufactured in the silicon wafer 101 by utilizing the micro-electromechanical processes or the semiconductor processes, the cup-structure 108 and the cup-structure 208, which have different shapes, can be produced on the top surface of one silicon wafer 101 in the meantime. According to this embodiment, the cup-structure 108 includes an inclined sidewall 108a, and the cup-structure 208 includes a vertical sidewall 108b.

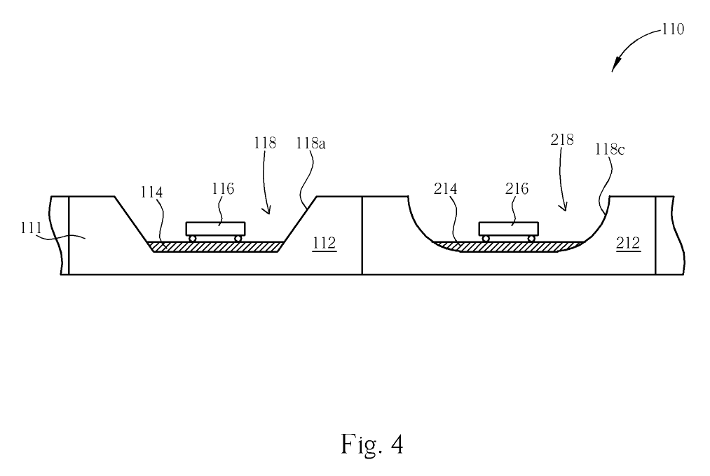

Other shapes of the cup-structures can be formed in the present invention according to different etching masks and different etching methods. Please refer to FIG. 4. FIG. 4 is a cross-sectional schematic diagram illustrating an opto-electronic package structure having Si-substrates according to a second preferred embodiment of the present invention. As shown in FIG. 4, an opto-electronic package structure 110 includes a silicon wafer 111, and at least two Si-substrates 112, 212 are defined in the silicon wafer 111. The Si-substrate 112 includes a plurality of connecters 114, a cup-structure 118, and at least an opto-electronic device 116 electrically connected to the connecters 114 through bumps. The Si-substrate 212 includes a plurality of connecters 214, a cup-structure 218, and at least an opto-electronic device 216 electrically connected to the connecters 214 through bumps. As shown in this embodiment, the cup-structure 118 includes an inclined sidewall 118a, and the cup-structure 218 includes an arc sidewall 118c.

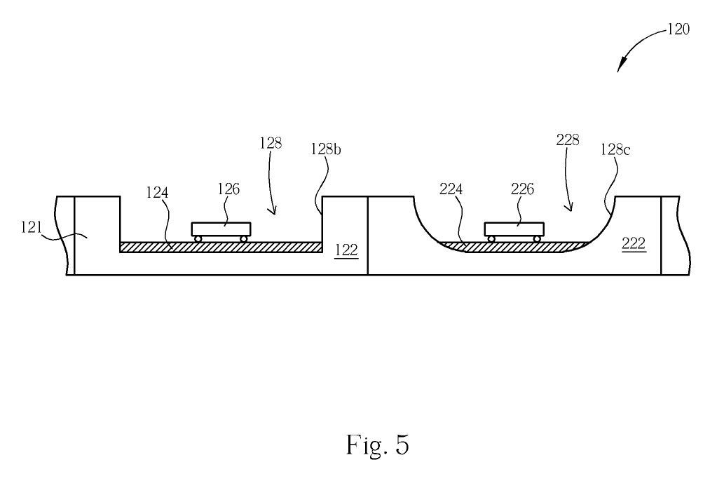

Please refer to FIG. 5. FIG. 5 is a cross-sectional schematic diagram illustrating an opto-electronic package structure having Si-substrates according to a third preferred embodiment of the present invention. As shown in FIG. 5, an opto-electronic package structure 120 includes a silicon wafer 121, and at least two Si-substrates 122, 222 are defined in the silicon wafer 121. The Si-substrate 122 includes a plurality of connecters 124, a cup-structure 128, and at least an opto-electronic device 126 electrically connected to the connecters 124 through bumps. The Si-substrate 222 includes a plurality of connecters 224, a cup-structure 228, and at least an opto-electronic device 226 electrically connected to the connecters 224 through bumps. As shown in this embodiment, the cup-structure 128 includes a vertical sidewall 128b, and the cup-structure 228 includes an arc sidewall 128c.

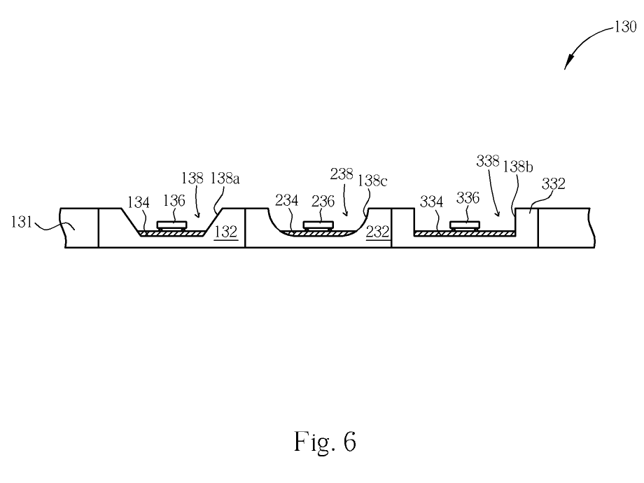

Please refer to FIG. 6. FIG. 6 is a cross-sectional schematic diagram illustrating an opto-electronic package structure having Si-substrates according to a fourth preferred embodiment of the present invention. As shown in FIG. 6, an opto-electronic package structure 130 includes a silicon wafer 131. At least three Si-substrates 132, 232, 332 are defined in the silicon wafer 131. The Si-substrate 132 includes a plurality of connecters 134, a cup-structure 138, and at least an opto-electronic device 136 electrically connected to the connecters 134 through bumps. The Si-substrate 232 includes a plurality of connecters 234, a cup-structure 238, and at least an opto-electronic device 236 electrically connected to the connecters 234 through bumps. The Si-substrate 332 includes a plurality of connecters 334, a cup-structure 338, and at least an opto-electronic device 336 electrically connected to the connecters 334 through bumps. As shown in this embodiment, the cup-structure 138 includes an inclined sidewall 138a, the cup-structure 338 includes a vertical sidewall 138b, and the cup-structure 238 includes an arc sidewall 138c.

The different shapes of the cup-structures are set for matching the different opto-electronic devices used in the opto-electronic package structures. For example, the above-mentioned opto-electronic devices can be red LEDs, blue LEDs, green LEDs, etc. so as to bring different optical effects.

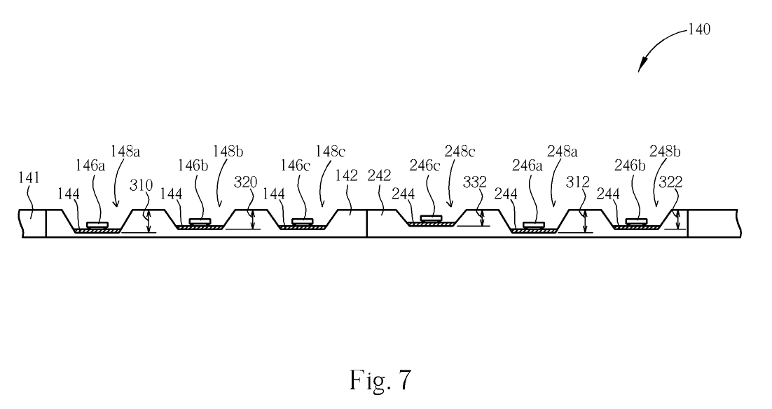

In another aspect, the shapes and the positions of the cup-structures can be adjusted according to the radiation of the opto-electronic devices and the required optical effect of the opto-electronic package structure. Please refer to FIG. 7. FIG. 7 is a cross-sectional schematic diagram illustrating an opto-electronic package structure having Si-substrates according to a fifth preferred embodiment of the present invention. As shown in FIG. 7, an opto-electronic package structure 140 includes a silicon wafer 141, and at least two Si-substrates 142, 242 are defined in the silicon wafer 141. As shown in this embodiment, the Si-substrate 142 includes a red LED component 146a, a blue LED component 146b, a green LED component 146c, a cup-structure 148a containing the red LED component 146a, a cup-structure 148b containing the blue LED component 146b, a cup-structure 148c containing the green LED component 146c, and a plurality of connecters 144 electrically connected to the LED components 146a, 146b, and 146c. The Si-substrate 242 includes a red LED component 246a, a blue LED component 246b, a green LED component 246c, a cup-structure 248a containing the red LED component 246a, a cup-structure 248b containing the blue LED component 246b, a cup-structure 248c containing the green LED component 246c, and a plurality of connecters 244 electrically connected to the LED components 246a, 246b, and 246c.

In the Si-substrate 142, the cup-structure 148a has a first depth 310, the cup-structure 148b and the cup-structure 148c have a second depth 320, and the first depth 310 is larger than the second depth 320. In the Si-substrate 242, the cup-structure 248a has a first depth 312, the cup-structure 248b has a second depth 322, and the cup-structure 248c has a third depth 332. The first depth 312 is larger than the second depth 322, and the second depth 322 is larger than the third depth 332. Accordingly, the Si-substrates 142, 242 can match the optical characteristic of the LED components 146a, 146b, 146c, 246a, 246b, and 246c.

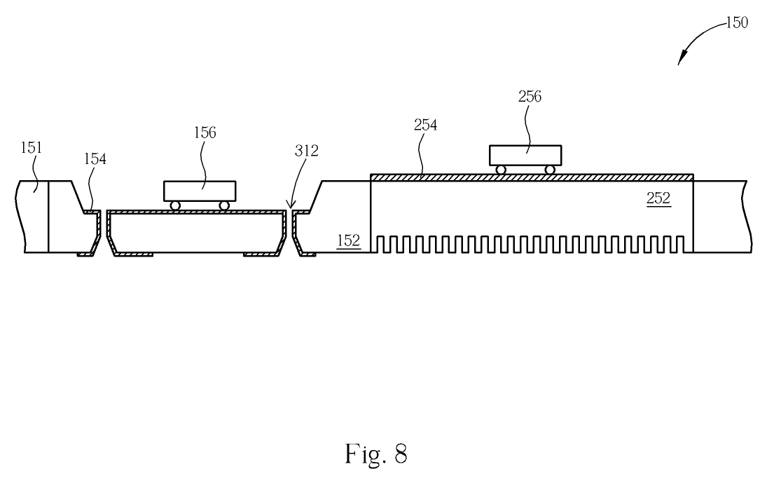

More opto-electronic package structures, which have different effects, can be integrated on one silicon wafer so as to increase the varieties and values of products. Please refer to FIG. 8. FIG. 8 is a cross-sectional schematic diagram illustrating an opto-electronic package structure having Si-substrates according to a sixth preferred embodiment of the present invention. As shown in FIG. 8, an opto-electronic package structure 150 includes silicon wafer 151, and at least two Si-substrates 152, 252 are defined in the silicon wafer 151. The Si-substrate 152 includes a plurality of connecters 154 and at least an opto-electronic device 156 electrically connected to the connecters 154. The Si-substrate 252 includes a plurality of connecters 254 and at least an opto-electronic device 256 electrically connected to the connecters 254. Accordingly, the Si-substrate 152 includes electric-conducting holes 312, and each connecter 154 on this Si-substrate 152 extends from the top surface of the Si-substrate 152 to the bottom surface of the Si-substrate 152 through at least one of the electric-conducting holes 312. On other hand, the opto-electronic device 256 is located on the top surface of the Si-substrate 252, and the top surface of the Si-substrate 252 is a substantially flat surface. The bottom surface of the Si-substrate 252 can be a fin structure so as to increase the heat-dissipating efficiency.

After all components of the above-mentioned opto-electronic package structure are completed, the Si-substrates can be separated from each other by means of a dicing process. As a result, the opto-electronic package structure is divided into a plurality of individual package structures, and each individual package structure can be thereafter electrically connected to the corresponding printed circuit board through the connecters of each Si-substrate.

Since the opto-electronic device is packaged with the Si-substrate in the present invention, and the Si-substrates can be manufactured by utilizing the micro-electromechanical processes or the semiconductor processes that are well-developed technologies, a variety of Si-substrates, which have different outline shapes, can be produced in a batch system. Thus, the opto-electronic package structure can be diversified and have fine structure.

Because the present invention chooses the Si-substrate to be the base of the opto-electronic package structure, and the heat transfer coefficient of silicon material is quite large, the heat-dissipating effect of the opto-electronic package structure can be increased. In addition, since silicon and an LED component are both made from semiconductor materials, the coefficient of thermal expansion (CTE) of silicon is approximate to the CTE of the LED. Therefore, using silicon to form the packaging substrate can increase the reliability of the produced opto-electronic package structure.

Furthermore, the opto-electronic package structure having the Si-substrate can be made in a batch system utilizing micro-electromechanical processes or semiconductor processes. According to the characteristics of Si-substrate and the arrangement of the components, such as the connecters, the opto-electronic device, the cup-structure and the flip-chip bump on Si-substrate, the present invention can simplify the complexity of the components in the opto-electronic package structure, and increase the optical effect, the heat-dissipating effect and the packaging reliability of the opto-electronic package structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An opto-electronic package structure having silicon-substrates (Si-substrates), comprising:
a silicon wafer, the silicon wafer defining a plurality of Si-substrates therein, each of the Si-substrates comprising a plurality of connecters and at least an opto-electronic device electrically connected to the connecters, and the Si-substrates comprising at least two different outline shapes.

2. The opto-electronic package structure of claim 1, wherein each of the Si-substrates has a top surface, and the top surfaces of the Si-substrates comprise a plurality of cup-structures.

3. The opto-electronic package structure of claim 2, wherein at least one of the cup-structures comprises an inclined sidewall, and at least one of the cup-structures comprises a vertical sidewall.

4. The opto-electronic package structure of claim 2, wherein at least one of the cup-structures comprises an inclined sidewall, and at least one of the cup-structures comprises an arc sidewall.

5. The opto-electronic package structure of claim 2, wherein at least one of the cup-structures comprises a vertical sidewall, and at least one of the cup-structures comprises an arc sidewall.

6. The opto-electronic package structure of claim 1, wherein at least one of the Si-substrates comprises a cup-structure having an inclined sidewall, at least one of the Si-substrates comprises a cup-structure having a vertical sidewall, and at least one of the Si-substrates comprises a cup-structure having an arc sidewall.

7. The opto-electronic package structure of claim 2, wherein at least one of the cup-structures has a first depth, at least one of the cup-structures has a second depth, and the first depth is larger than the second depth.

8. The opto-electronic package structure of claim 1, wherein each of the opto-electronic devices comprises a light emitting diode (LED).

9. The opto-electronic package structure of claim 8, wherein at least one of the Si-substrates comprises a red LED, at least one of the Si-substrates comprises a green LED, and at least one of the Si-substrates comprises a blue LED.

10. The opto-electronic package structure of claim 8, wherein at least one of the Si-substrates comprises a red LED, a green LED, and a blue LED.

11. The opto-electronic package structure of claim 1, wherein each of the Si-substrates comprises a bottom surface, and at least one of the bottom surfaces comprises a fin structure.

12. The opto-electronic package structure of claim 1, wherein the connecters of each Si-substrate are electrically connected to a printed circuit board.

13. The opto-electronic package structure of claim 1, wherein each of the connecters is a metal layer.
